(19) United States
(12) Patent Application Publication
(10) Pub. No.: US 2016/0021749 A1
(43) Pub. Date: Jan. 21, 2016

(54) PACKAGE BOARD, METHOD OF MANUFACTURING THE SAME AND STACK TYPE PACKAGE USING THE SAME

(71) Applicant: SAMSUNG ELECTRO-MECHANICS CO., LTD., Suwon-Si (KR)

(72) Inventors: Kang Wook BONG, Suwon-Si (KR); Myung Sam KANG, Suwon-Si (KR); Yong Wan JI, Suwon-Si (KR); Hye Won JUNG, Suwon-Si (KR); Yong Jin PARK, Suwon-Si (KR); Young Gwan KO, Suwon-Si (KR)

(21) Appl. No.: 14/736,128

(22) Filed: Jun. 10, 2015

(30) Foreign Application Priority Data
Jul. 15, 2014 (KR) 10-2014-0089156

(51) Int. Cl. H05K 1/16; H05K 1/11; H05K 3/42; H05K 1/18

(52) U.S. Cl. CPC H05K 1/16; H05K 1/183; H05K 1/115; H05K 3/422

(57) ABSTRACT

There are provided a package board, a method of manufacturing the same, and a stack type package using the same. The package board according to an exemplary embodiment of the present invention includes a first insulating layer formed with a cavity and an external connection terminal formed to penetrate through the first insulating layer and have one end protruding to an outside of one surface of the first insulating layer.

### CROSS-REFERENCE TO RELATED APPLICATION

This application claims the benefit of Korean Patent Application No. 10-2014-0089156, filed on Jul. 15, 2014, entitled “Package Board, Method Of Manufacturing The Same And Stack Type Package Using The Same” which is hereby incorporated by reference in its entirety into this application.

### BACKGROUND

The present disclosure relates to a package board, a method of manufacturing the same, and a stack type package using the same.

Recently, electronic industries have adopted a mounting technology of using a multi-layer printed circuit board which may be highly densified and integrated at the time of mounting components to implement small and thin electronic devices. The high-density and high-integration multi-layer printed circuit board has been implemented by advancement in element technology which may implement micro circuits, bumps, and the like on a substrate. Recently, a semiconductor package such as a system in package (SIP), a chip sized package (CSP), and a flip chip package (FCP) configured as a package by mounting electronic devices on a printed circuit board in advance has been actively developed. Further, a package on package (POP) in which a control device and a memory device are implemented as one package form to improve miniaturization and performance of a high-performance smart phone has been developed. The package on package may be implemented by individually packaging the control device and the memory device and then stacking and connecting them.

### RELATED ART DOCUMENT

### Patent Document

(Patent Document 1) U.S. Pat. No. 5,986,209

### SUMMARY

An aspect of the present invention may provide a package board capable of implementing a fine pitch, a method for manufacturing the same, and a stack type package using the same.

Another aspect of the present invention may provide a package board capable of reducing a thickness of a package, a method of manufacturing the same, and a stack type package using the same.

According to an aspect of the present disclosure, a package board may include a first insulating layer formed with a cavity and an external connection terminal formed to penetrate through the first insulating layer and have one end protruding to an outside of one surface of the first insulating layer.

The external connection terminal may include a first plating layer formed to penetrate through the first insulating layer and formed to protrude to the outside of the one surface of the first insulating layer; and a second plating layer formed on the first plating layer protruding to the outside.

The external connection terminal may include a first plating layer formed inside the first insulating layer and formed in a form collapsing from the one surface of the first insulating layer and conductive balls formed on the first plating layer, some of the conductive balls being formed to be positioned inside the first insulating layer and others being formed to be positioned outside the first insulating layer.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exemplified diagram illustrating a package board according to a first exemplary embodiment of the present disclosure;

FIGS. 2 through 10 are exemplified diagrams illustrating a method of manufacturing the package board according to the first exemplary embodiment of the present invention;

FIG. 11 is an exemplified diagram illustrating a package board according to a second exemplary embodiment of the present disclosure;

FIGS. 12 through 14 are exemplified diagrams illustrating a method of manufacturing the package board according to the second exemplary embodiment of the present invention;

FIG. 15 is an exemplified diagram illustrating a package board according to a third exemplary embodiment of the present disclosure;

FIGS. 16 through 26 are exemplified diagrams illustrating a method of manufacturing the package board according to the third exemplary embodiment of the present invention;

FIG. 27 is an exemplified diagram illustrating a package board according to a fourth exemplary embodiment of the present disclosure;

FIGS. 28 through 30 are exemplified diagrams illustrating a method of manufacturing the package board according to the fourth exemplary embodiment of the present invention; and

FIG. 31 is an exemplified diagram illustrating a stack type package according to the exemplary embodiment of the present disclosure.

### DESCRIPTION OF EMBODIMENTS

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

### First Exemplary Embodiment

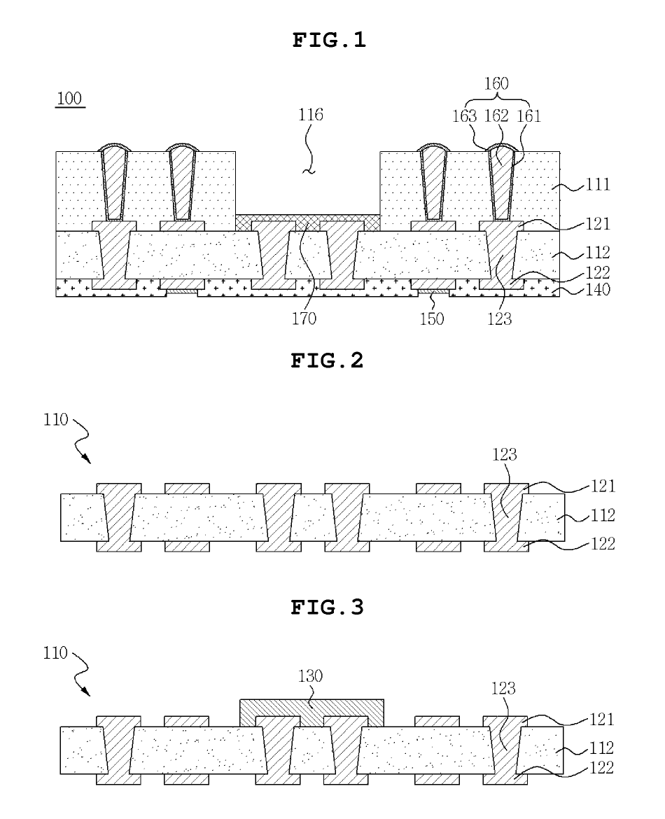

FIG. 1 is an exemplified diagram illustrating a package board according to a first exemplary embodiment of the present disclosure.

Referring to FIG. 1, a package board 100 according to a first exemplary embodiment of the present invention includes a first insulating layer 111, a second insulating layer 112, a first circuit pattern 121, a second circuit pattern 122, an external connection terminal 160, a via 123, a solder resist layer 140, a surface treatment layer 150, and an external protective layer 170.

For convenience of description and understanding of exemplary embodiments of the present invention, with reference to FIG. 1, one direction will be described as an upward direction and the other direction will be described as a downward direction.

According to the first exemplary embodiment of the present disclosure, the first insulating layer 111 is made of the composite polymer resin which is generally used as an interlayer insulating material. For example, the first insulating layer 111 may be made of the epoxy based resin, such as prepreg, ajinomoto build up film (ABF), FR-4, and bismaleimide triazine (BT).

According to the first exemplary embodiment of the present invention, the first insulating layer 111 includes a cavity 116. According to the first exemplary embodiment of the present disclosure, the cavity 116 is an empty space which is formed inwardly from an upper surface of the first insulating layer 111. According to the first exemplary embodiment of the present invention, an inside of the cavity 116 is provided with electronic devices (not illustrated) which are mounted on another package board (not illustrated). As such, since the electronic devices (not illustrated) are disposed inside the cavity 116 of the package board 100, an overall thickness of the package is reduced when a stack type package (not illustrated) is formed.

According to the first exemplary embodiment of the present invention, a first circuit pattern 121 is formed on a lower surface of the first insulating layer 111 and is formed to be embedded in the first insulating layer 111. Here, the lower surface of the first insulating layer 111 also becomes an upper surface of the second insulating layer 112. Further, some of the first circuit patterns 121 which are formed on the lower surface of the first insulating layer 111 or the upper surface of the second insulating layer 112 are formed at a lower portion of the cavity 116. According to the first exemplary embodiment of the present disclosure, the first circuit pattern 121 is made of conductive materials which are generally used in a circuit board field. For example, the first circuit pattern 121 may be made of copper (Cu).

According to the first exemplary embodiment of the present disclosure, an external connection terminal 160 is formed to penetrate through the first insulating layer 111. Further, the external connection terminal 160 is formed to have an upper end protruding to an outside of the first insulating layer 111 and a lower end bonded to the first circuit pattern 121.

According to the first exemplary embodiment of the present invention, the external connection terminal 160 includes a seed layer 161, a first plating layer 162, and a second plating layer 163.

According to the first exemplary embodiment of the present invention, the seed layer 161 is formed on an inner wall of the through hole 115 which penetrates through the first insulating layer 111. At the time of forming the first plating layer 162, the seed layer 161 serves as a lead wire for electroplating.

According to the first exemplary embodiment of the present invention, the first plating layer 162 is formed to protrude to the outside of the first insulating layer 111 by penetrating through the first insulating layer 111. In this case, an upper end of the first plating layer 162 protrudes to the outside of the first insulating layer 111 and a lower end thereof is bonded to the first circuit pattern 121.

Further, according to the first exemplary embodiment of the present invention, the second plating layer 163 is formed to enclose the first plating layer 162 which protrudes from the first insulating layer 111. According to the first exemplary embodiment of the present invention, the seed layer 161, the first plating layer 162, and the second plating layer 163 are made of conductive metals which are generally used in the circuit board field. Further, the first plating layer 162 and the second plating layer 163 may be made of different materials. For example, the first plating layer 162 may be made of copper and the second plating layer 163 may be made of tin (TiN).

According to the first exemplary embodiment of the present invention, a spaced distance between the package board 100 and another package board (not illustrated) is reduced due to the cavity 116, and thus the package board 100 may directly contact an external connection pad (not illustrated) of another package board. That is, a portion protruding from the first insulating layer 111 of the external connection terminal 160 directly contacts another package board (not illustrated). Therefore, the existing external connection terminals such as a solder ball may be omitted. Further, a fine pitch of a circuit pattern which is limited by a size of the solder ball as in the related art may be implemented due to the omission of the solder ball.

According to the first exemplary embodiment of the present invention, the second insulating layer 112 is formed on the lower surface of the first insulating layer 111 by the cavity 116 and the external connection terminal 160. The second insulating layer 112 may be generally made of the composite polymer resin used as the interlayer insulating material. For example, the first insulating layer 111 may be made of the epoxy based resin, such as prepreg, ajinomoto build up film (ABF), FR-4, and bismaleimide triazine (BT). According to the first exemplary embodiment of the present invention, the first insulating layer 111 and the second insulating layer 112 may be made of the same material or may be made of different materials.

According to the first exemplary embodiment of the present invention, the second circuit pattern 122 is formed on the lower surface of the second insulating layer 112 and is formed to protrude from the second insulating layer 112. According to the first exemplary embodiment of the present disclosure, the second circuit pattern 122 is made of conductive materials which are generally used in the circuit board field. For example, the second circuit pattern 122 may be made of copper (Cu).

According to the first exemplary embodiment of the present disclosure, the via 123 penetrates through the second insulating layer 112, and thus an upper end of the via 123 is bonded to the first circuit pattern 121 and a lower end thereof is bonded to the second circuit pattern 122. The first circuit pattern 121 and the second circuit pattern 122 are electrically connected to each other by the so formed via 123. According to the first exemplary embodiment of the present disclosure, the via 123 is made of conductive materials which are generally used in the circuit board field. For example, the via 123 may be made of copper.

The first exemplary embodiment of the present disclosure describes an example in which the upper surface of the second insulating layer 112 is provided with the first circuit pattern 121 and the lower surface thereof is provided with the second circuit pattern 122, but is not limited thereto. For example, although the second insulating layer 112 is not illustrated, the inside of the second insulating layer 112 may be further provided with internal circuit patterns of at least one layer. In this case, internal vias for electrical connection among the internal circuit pattern of each layer, the first circuit pattern 121, and the second circuit pattern 122 may be further formed.

Further, the first exemplary embodiment of the present disclosure describes an example in which the second insulating layer 112, the via 123, the second circuit pattern 122 are formed, but a configuration thereof may be omitted according to a selection of those skilled in the art.

According to the first exemplary embodiment of the present disclosure, a solder resist layer 140 is formed on the lower surface of the second insulating layer 112 and is formed to enclose the second circuit pattern 122. At the time of soldering electronic devices and external components such as a substrate with the package board 100 to connect among them, the solder resist layer 140 protects the second circuit pattern 122 from the soldering. Further, the solder resist layer 140 prevents the second circuit pattern 122 from being oxidized. The solder resist layer 140 is made of a heat resistant covering material. According to the first exemplary embodiment of the present disclosure, the solder resist layer 140 is patterned to expose a portion which is connected to external components in the second circuit pattern 122.

According to the first exemplary embodiment of the present disclosure, the surface treatment layer 150 is formed on the second circuit pattern 122 which is exposed to the outside by the solder resist layer 140. The surface treatment layer 150 is formed to prevent the second circuit pattern 122 which is exposed to the outside from corroding and being oxidized due to the outside environment. For example, the surface treatment layer 150 includes at least one of nickel, tin, gold, and palladium or is formed as organic solder ability preservative (OSP). However, a kind of the surface treatment layer 150 is not limited thereto, and therefore any of those known to those skilled in the art may be used.

According to the first exemplary embodiment of the present disclosure, the external protective layer 170 is formed to enclose the first circuit pattern 121 which is positioned at the lower portion of the cavity 116. The external protective layer 170 is also formed to prevent the first circuit pattern 121 from being damaged from the outside environment. According to the first exemplary embodiment of the present disclosure, as the external protective layer 170, any of those known to those skilled in the art which may protect the circuit patterns may be used. For example, the external protective layer 170 is made of the same material as the solder resist layer 140.

According to the first exemplary embodiment of the present disclosure, the solder resist layer 140, the surface treatment layer 150, and the external protective layer 170 may be omitted according to the selection of those skilled in the art.

FIGS. 2 through 10 are exemplified diagrams illustrating a method of manufacturing the package board according to the first exemplary embodiment of the present invention.

According to the first exemplary embodiment of the present disclosure, FIGS. 2 through 10 illustrate a method for manufacturing a package board 100 of FIG. 1. For convenience of description and understanding of exemplary embodiments of the present invention, one direction will be described as an upward direction and the other direction will be described as a downward direction.

Referring to FIG. 2, a core substrate 110 is provided.

According to the first exemplary embodiment of the present disclosure, the core substrate 110 includes the second insulating layer 112, the first circuit pattern 121, the second circuit pattern 122, and the via 123.

According to the first exemplary embodiment of the present disclosure, the second insulating layer 112 is made of the composite polymer resin which is generally used as an interlayer insulating material. For example, the second insulating layer 112 may be made of the epoxy based resin, such as prepreg, ajinomoto build up film (ABF), FR-4, and bismaleimide triazine (BT).

According to the first exemplary embodiment of the present invention, the first circuit pattern 121 is formed on the upper surface of the second insulating layer 112 and is formed to protrude from the upper surface of the second insulating layer 112.

According to the first exemplary embodiment of the present invention, the second circuit pattern 122 is formed on the lower surface of the second insulating layer 112 and is formed to protrude from the lower surface of the second insulating layer 112.

Further, according to the first exemplary embodiment of the present disclosure, the via 123 penetrates through the inside of the second insulating layer 112, and thus the upper end of the via 123 is bonded to the first circuit pattern 121 and the lower end thereof is bonded to the second circuit pattern 122. The first circuit pattern 121 and the second circuit pattern 122 are electrically connected to each other by the so formed via 123. The first exemplary embodiment of the present disclosure illustrates an example in which the via 123 is formed, but the via 123 may also be omitted according to the selection of those skilled in the art.

According to the first exemplary embodiment of the present disclosure, the first circuit pattern 121, the second circuit pattern 122, and the via 123 are made of the conductive material which is generally used in the circuit board field. For example, the first circuit pattern 121, the second circuit pattern 122, and the via 123 are made of copper.

According to the first exemplary embodiment of the present disclosure, the core substrate 110 may be formed by any method known in the circuit substrate field, such as a tenting method, a semi-additive process (SAP), and a modify semi-additive process (MSAP).

Further, although not illustrated in the first exemplary embodiment of the present disclosure, the internal circuit patterns (not illustrated) of at least one layer and the internal via (not illustrated) may be further formed in the second insulating layer 112 according to the selection of those skilled in the art.

Referring to FIG. 3, an etching protective layer 130 is formed.

According to the first exemplary embodiment of the present disclosure, the etching protective layer 130 is formed to prevent the first circuit pattern 121 from being damaged at the time of forming the cavity (not illustrated) later. Therefore, the etching protective layer 130 is formed to enclose the first circuit pattern 121 which is positioned in a region in which the cavity (not illustrated) is formed. According to the first exemplary embodiment of the present disclosure, the etching protective layer 130 may be made of any material which may protect the first circuit pattern 121 from a cavity forming process. In this case, the etching protective layer 130 is made of a material different from that of the second insulating layer 112 and thus is made of a material which may be selectively stripped.

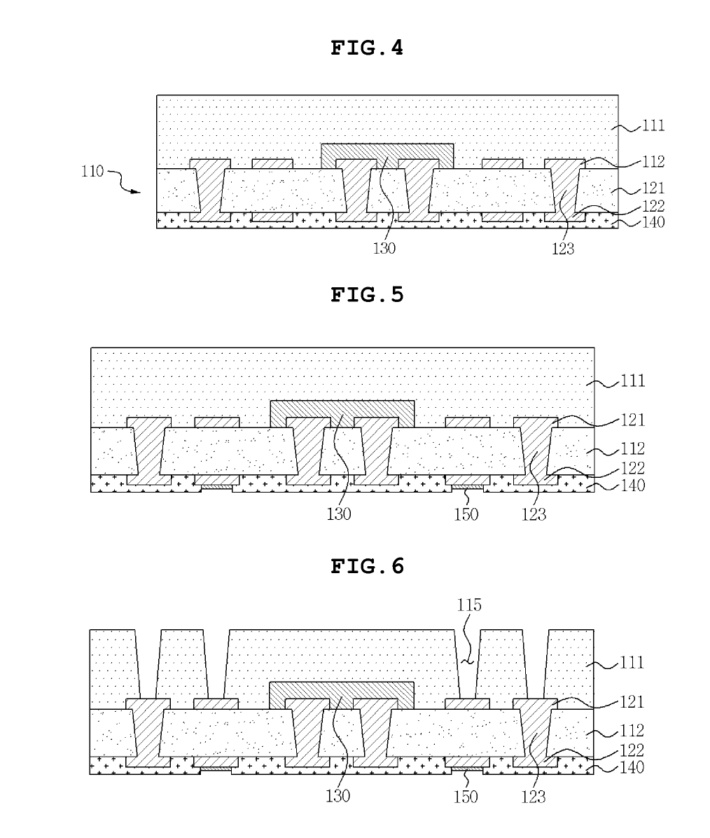

Referring to FIG. 4, the first insulating layer 111 and the solder resist layer 140 are formed.

According to the first exemplary embodiment of the present disclosure, the first insulating layer 111 and the solder resist layer 140 may be stacked on the core substrate 110 in a film type. Alternatively, the first insulating layer 111 and the solder resist layer 140 may be coated on the core substrate 110 in a liquid type.

According to the first exemplary embodiment of the present disclosure, the first insulating layer 111 is formed at an upper portion of the core substrate 110 and is thus formed to enclose the first circuit pattern 121 and the etching protective layer 130. According to the first exemplary embodiment of the present disclosure, the first insulating layer 111 is made of the composite polymer resin which is generally used as the interlayer insulating material. For example, the first insulating layer 111 may be made of the epoxy based resin, such as prepreg, ajinomoto build up film (ABF), FR-4, and bismaleimide triazine (BT).

Further, according to the first exemplary embodiment of the present disclosure, the solder resist layer 140 is formed on the lower surface of the core substrate 110 and is formed to enclose the second circuit pattern 122. At the time of soldering electronic devices and external components such as a substrate with the package board 100 to connect among them, the so formed solder resist layer 140 is formed to protect the second circuit pattern 122 from the soldering. Further, the solder resist layer 140 prevents the second circuit pattern 122 from being oxidized. According to the first exemplary embodiment of the present disclosure, the solder resist layer 140 is made of a heat resistant covering material.

Referring to FIG. 5, the solder resist layer 140 is patterned.

According to the first exemplary embodiment of the present disclosure, the solder resist layer 140 is patterned to expose a portion, which is connected to external components in the second circuit pattern 122, to the outside. For example, the solder resist layer 140 is patterned by exposure and development processes.

Further, the solder resist layer 140 is patterned and then the surface treatment layer 150 is formed on the second circuit pattern 122 which is exposed to the outside. The surface treatment layer 150 is formed to prevent the second circuit pattern 122 which is exposed to the outside from corroding and being oxidized due to the outside environment. For example, the surface treatment layer 150 is plated with at least one of nickel, tin, gold, and palladium or is formed by coating organic solder ability preservative (OSP). However, a kind and a method of the surface treatment layer 150 are not limited thereto, and therefore those known to those skilled in the art may be used.

Referring to FIG. 6, the through hole 115 is formed.

According to the first exemplary embodiment of the present invention, the through hole 115 is formed to expose the first circuit pattern 121 by penetrating through the first insulating layer 111. The through hole 115 is formed in a region in which the external connection terminal (not illustrated) connected to the external components is formed. According to the first exemplary embodiment of the present disclosure, when the first insulating layer 111 is made of a photosensitive material, the through hole 115 may be formed by exposure and development processes. Alternatively, the though hole 115 may be formed by a laser drill. According to the first exemplary embodiment of the present disclosure, a method for forming a through hole 115 is not limited to the exposure and development processes and the laser drill. The through hole 115 may be formed by any method for forming a hole in the circuit board field.

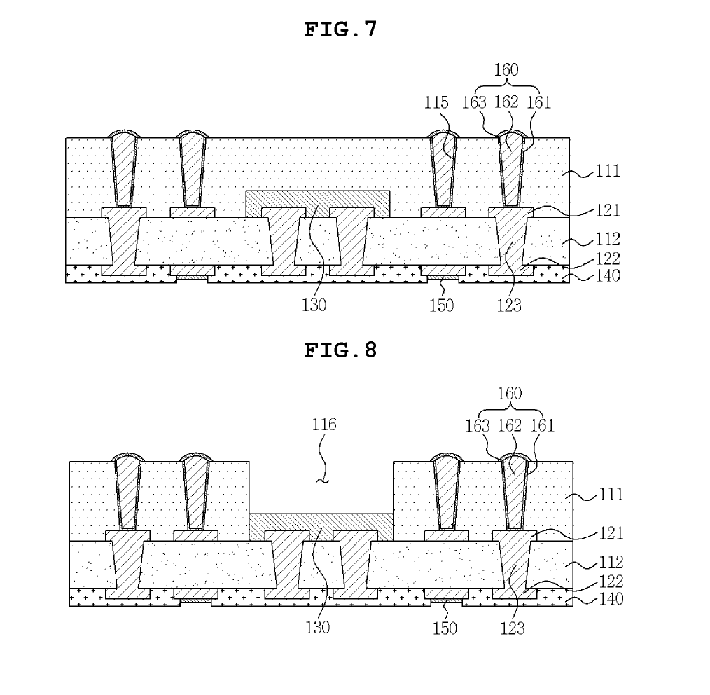

Referring to FIG. 7, the external connection terminal 160 is formed.

According to the first exemplary embodiment of the present invention, the external connection terminal 160 includes the seed layer 161, the first plating layer 162, and the second plating layer 163.

According to the first exemplary embodiment of the present disclosure, first, the seed layer 161 is formed on the inner wall of the through hole 115. In this case, the seed layer 161 may be formed only on the inner wall of the through hole 115. In this case, an etching resist (not illustrated) which exposes the through hole 115 is formed on the first insulating layer 111 and then suffers from electroless plating, such that the seed layer 161 may be formed only on the inner wall of the through hole 115. Alternatively, the seed layer 161 may be formed both on the inner wall of the through hole 115 and the upper surface of the first insulating layer 111.

According to the first exemplary embodiment of the present disclosure, the seed layer 161 is formed by the electroless plating method. For example, the seed layer 161 may be made of copper.

Next, the first plating layer 162 is formed in the through hole 115 formed with the seed layer 161 by the electroplating method. According to the first exemplary embodiment of the present disclosure, the first plating layer 162 is formed to protrude from the upper surface of the first insulating layer 111. That is, the first plating layer 162 is formed by performing overplating on the through hole 115. For example, the first plating layer 162 may be made of copper.

The first exemplary embodiment of the present disclosure illustrates an example in which the seed layer 161 and the first plating layer 162 are made of copper, but the material is not limited thereto. The seed layer 161 and the first plating layer 162 may be made of any of the conductive materials which are used for plating in the circuit board field.

According to the first exemplary embodiment of the present disclosure, when the seed layer 161 is formed both on the upper surface of the first insulating layer 111 and the inner wall of the through hole 115, a process of forming the first plating layer 162 and then removing the seed layer 161 exposed to the outside is performed.

According to the first exemplary embodiment of the present disclosure, the first plating layer 162 is formed and then the second plating layer 163 is formed. According to the first exemplary embodiment of the present disclosure, the second plating layer 163 is formed to enclose the first plating layer 162 which is exposed to the outside of the first insulating layer 111. The second plating layer 163 is formed by at least one of an electroless plating method and the electroplating method. Further, the second plating layer 163 may be made of any of the conductive materials which are used for plating in the circuit board field, but is made of a material different from that of the first plating layer 162. For example, the second plating layer 163 may be made of tin (TiN).

Although not described and illustrated in the first exemplary embodiment of the present disclosure, the fact that any one of the plating resist (not illustrated) and the etching resist (not illustrated) may be used at the time of forming the external connection terminal 160 is apparent to those skilled in the art.

Referring to FIG. 8, the cavity 116 is formed.

According to the first exemplary embodiment of the present disclosure, the cavity 116 is formed in the first insulating layer 111. The cavity 116 is formed to expose the etching protective layer 130. According to the first exemplary embodiment of the present disclosure, the cavity 116 is formed by the exposure and development processes. However, the method for forming a cavity 116 is not limited thereto. For example, the cavity 116 may also be formed by the laser drill. All or some of the electronic devices (not illustrated) are inserted into the so formed cavity 116.

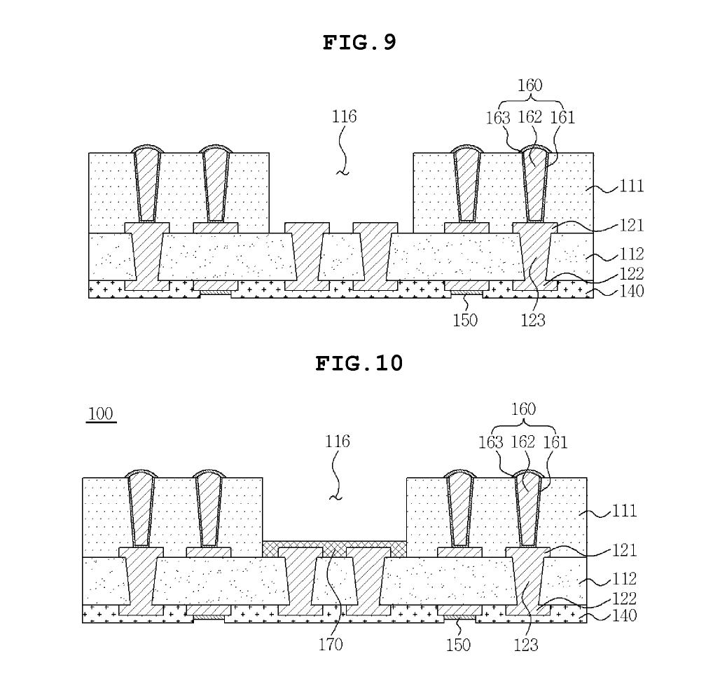

Referring to FIG. 9, the etching protective layer 130 (FIG. 8) is removed.

According to the first exemplary embodiment of the present disclosure, the etching protective layer 130 (FIG. 8) is removed and thus the first circuit pattern 122 which is formed at the lower portion of the cavity 116 is exposed to the outside.

Referring to FIG. 10, the external protective layer 170 is formed.

According to the first exemplary embodiment of the present disclosure, the external protective layer 170 is formed to protect the first circuit pattern 121 which is exposed to the outside from the outside environment by the cavity 116. Therefore, the external protective layer 170 is formed to enclose the first circuit pattern 121 within the cavity 116. The external protective layer 170 may be made of any material which may protect the first circuit pattern 121 from the outside. For example, the external protective layer 170 is made of the same material as the solder resist layer 140.

As such, the package board 100 according to the first exemplary embodiment of the present invention is formed by the processes illustrated in FIGS. 2 through 10.

### Second Exemplary Embodiment

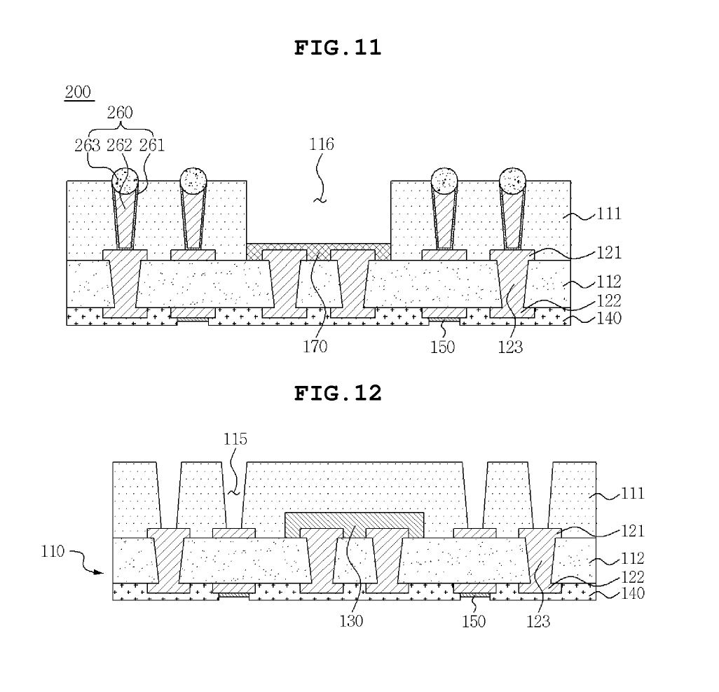

FIG. 11 is an exemplified diagram illustrating a package board according to a second exemplary embodiment of the present disclosure.

A package board 200 according to a second exemplary embodiment of the present invention includes the first insulating layer 111, the second insulating layer 112, the first circuit pattern 121, the second circuit pattern 122, an external connection terminal 260, the via 123, the solder resist layer 140, the surface treatment layer 150, and the external protective layer 170.

The first insulating layer 111, the second insulating layer 112, the first circuit pattern 121, the second circuit pattern 122, the via 123, the solder resist layer 140, the surface treatment layer 150, and the external protective layer 170 of the package board 200 according to the second exemplary embodiment of the present invention are the same as the package board 100 according to the first exemplary embodiment of the present invention of FIG. 1. Therefore, the description of the overlapping components will be omitted and a detailed description thereof will refer to FIG. 1.

The external connection terminal 260 of the package board 200 according to the second exemplary embodiment of the present invention includes a seed layer 261, a first plating layer 262, and conductive balls 263.

According to the second exemplary embodiment of the present invention, the seed layer 261 is formed on an inner wall of the through hole 115 which penetrates through the first insulating layer 111. At the time of forming the first plating layer 261, the seed layer 262 serves as a lead wire for electroplating.

According to the second exemplary embodiment of the present invention, the first plating layer 262 is formed in the through hole 115 in which the seed layer 261 is formed. According to the second exemplary embodiment of the present invention, the first plating layer 262 is formed so as not to completely fill the through hole 115. That is, the first plating layer 262 is formed to collapse from the upper surface of the first insulating layer 111. According to the second exemplary embodiment of the present disclosure, the seed layer 261 and the first plating layer 262 are made of conductive materials which are used in the circuit board field. For example, the seed layer 261 and the first plating layer 262 may be made of copper.

According to the second exemplary embodiment of the present disclosure, the conductive ball 263 is formed on the first plating layer 262. That is, some of the conductive balls 263 are positioned inside the through hole 115 and the rest thereof are formed to protrude to the outside of the first insulating layer 111. For example, the conductive ball 263 is a solder ball.

A spaced distance between the package board 200 according to the second exemplary embodiment of the present invention and another package board (not illustrated) is reduced due to the cavity 116. Further, the external connection terminal 260 includes the first plating layer 262 and the conductive balls 263 and thus may be sufficiently electrically connected to another package board (not illustrated) even by the conductive ball 263 having a smaller volume than that of the related art. Further, it is possible to implement the fine pitch of the circuit pattern since the volume of the used conductive ball 263 is reduced.

FIGS. 12 through 14 are exemplified diagrams illustrating a method of manufacturing the package board according to the second exemplary embodiment of the present invention.

Referring to FIG. 12, the etching protective layer 130, the first insulating layer 111, and the solder resist layer 140 are formed on the core substrate 110. Further, the first insulating layer 111 is formed on the core substrate 110 and then the through hole 115 is formed.

According to the second exemplary embodiment of the present disclosure, the method for forming an etching protective layer 130, the first insulating layer 111, the solder resist layer 140, and the through hole 115 on the core substrate 110 is the same as FIGS. 2 through 6 which illustrate the first exemplary embodiment of the present invention. Therefore, the process of forming the through hole 115 in the process of preparing the core substrate 110 will be described in detail with reference to FIGS. 2 through 6.

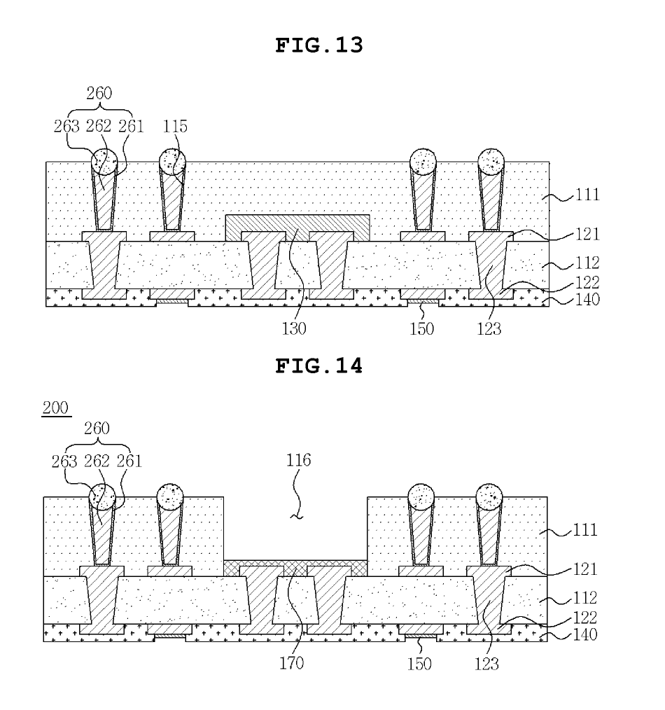

Referring to FIG. 13, the external connection terminal 260 is formed.

According to the second exemplary embodiment of the present disclosure, first, the seed layer 261 is formed on the inner wall of the through hole 115. According to the second exemplary embodiment of the present disclosure, the seed layer 261 is formed by the electroless plating method. For example, the seed layer 261 may be made of copper. According to the second exemplary embodiment of the present disclosure, the etching resist (not illustrated) which exposes the through hole 115 is formed on the first insulating layer 111 and then suffers from the electroless plating, such that the seed layer 261 may be formed only on the inner wall of the through hole 115. Alternatively, the seed layer 261 may be formed both on the inner wall of the through hole 115 and the upper surface of the first insulating layer 111.

Next, the first plating layer 261 is formed in the through hole 115 formed with the seed layer 262 by the electroplating method. According to the second exemplary embodiment of the present disclosure, the first plating layer 262 is formed to collapse from the upper surface of the first insulating layer 111. That is, the first plating layer 262 is not yet plated in the through hole 115 and thus is formed to have a lower height than the upper surface of the first insulating layer 111. For example, the first plating layer 262 may be made of copper.

The second exemplary embodiment of the present disclosure illustrates an example in which the seed layer 261 and the first plating layer 262 are made of copper, but the material is not limited thereto. The seed layer 261 and the first plating layer 262 may be made of any of the conductive materials which are used for plating in the circuit board field.

According to the second exemplary embodiment of the present disclosure, a process of forming the first plating layer 262 and then removing the seed layer 261 exposed to the outside is performed.

According to the second exemplary embodiment of the present disclosure, the first plating layer 262 is formed and then the conductive ball 263 is formed. According to the second exemplary embodiment of the present disclosure, the conductive balls 263 are formed on the first plating layer 262 and thus some of the conductive balls 263 are positioned inside the through hole 115 and the rest thereof are positioned to protrude from the first insulating layer 111. For example, the conductive ball 263 is formed of a solder.

According to the second exemplary embodiment of the present disclosure, the external connection terminal 260 which includes the seed layer 261, the first plating layer 262, and the conductive ball 263 is formed by the foregoing method.

Referring to FIG. 14, the cavity 116 and the external protective layer 170 are formed.

According to the second exemplary embodiment of the present disclosure, the detailed description from the process of forming the cavity 116 to the process of forming the external protective layer 170 will refer to FIGS. 8 through 10 which are the first exemplary embodiment of the present invention.

As such, the package board 200 according to the second exemplary embodiment of the present invention is formed by the processes illustrated in FIGS. 12 through 14.

### Third Exemplary Embodiment

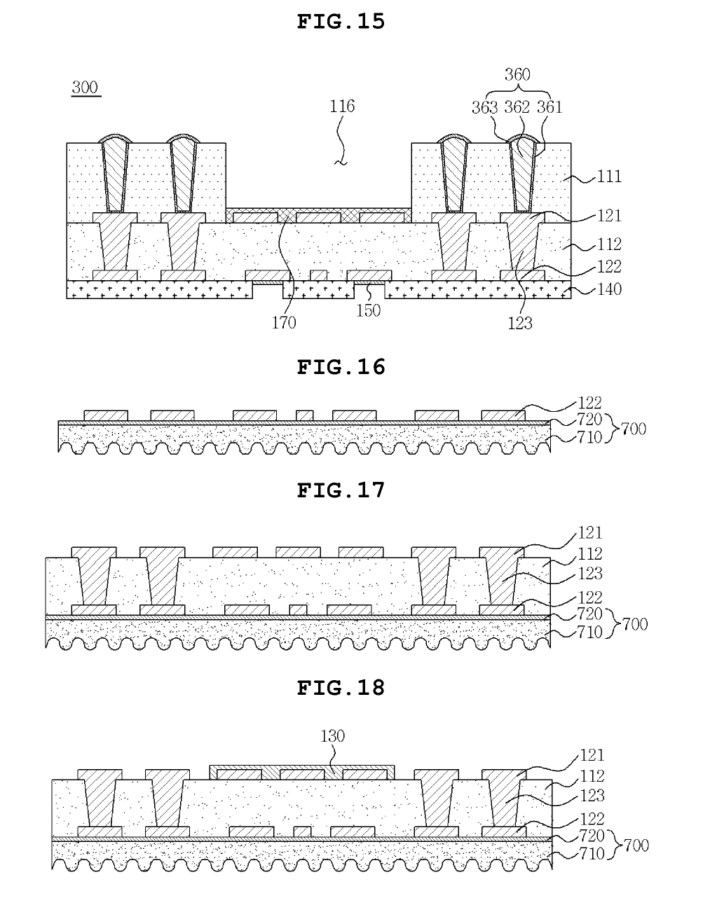

FIG. 15 is an exemplified diagram illustrating a package board according to a third exemplary embodiment of the present disclosure.

A package board 300 according to a third exemplary embodiment of the present invention includes the first insulating layer 111, the second insulating layer 112, the first circuit pattern 121, the second circuit pattern 122, an external connection terminal 360, the via 123, the solder resist layer 140, the surface treatment layer 150, and the external protective layer 170.

The first insulating layer 111, the second insulating layer 112, the first circuit pattern 121, the external connection terminal 360, the via 123, the solder resist layer 140, the surface treatment layer 150, and the external protective layer 170 of the package board 300 according to the third exemplary embodiment of the present invention are the same as the package board 100 according to the first exemplary embodiment of the present invention of FIG. 1. Therefore, the description of the overlapping components will be omitted and a detailed description thereof will refer to FIG. 1.

According to the third exemplary embodiment of the present disclosure, the second circuit pattern 122 is formed at the lower surface of the second insulating layer 112. In this case, the second circuit pattern 122 is embedded in the second insulating layer 112 and is formed that only the lower surface thereof is exposed to the outside. According to the third exemplary embodiment of the present disclosure, the second circuit pattern 122 is made of the conductive material which is known in a circuit board field. For example, the second circuit pattern 122 may be made of copper.

FIGS. 16 through 26 are exemplified diagrams illustrating a method of manufacturing the package board according to the third exemplary embodiment of the present invention.

For convenience of explanation and understanding, the third exemplary embodiment of the present invention illustrates an example in which the package board is formed on one surface (upper portion) of a carrier substrate. However, the present invention is not limited thereto and although not illustrated in the drawings, the same process is performed on both surfaces of the carrier substrate and thus two package boards may be finally manufactured.

Referring to FIG. 16, the second circuit pattern 122 is formed on a carrier substrate 700.

According to the third exemplary embodiment of the present invention, when an insulating layer and a circuit layer for the package board are formed, the carrier substrate 700 is a component to support the insulating layer and the circuit layer.

According to the third exemplary embodiment of the present invention, the carrier substrate 700 has a structure in which a metal layer 720 is stacked on a carrier core 710.

For example, the carrier core 710 is made of an insulating material. However, a material of the carrier core 710 is not limited to an insulating material, but therefore the carrier core 710 is made of a metal material or may have a structure in which the insulating layer and the metal layer are stacked in at least one layer.

For example, the metal layer 720 may be made of copper. However, the material of the metal layer 720 is not limited to copper, and therefore any conductive material which is used in the circuit board field may be applied without being limited.

According to the third exemplary embodiment of the present disclosure, the second circuit 122 is formed on the carrier core 700. A method for forming a second circuit pattern 122 on the carrier substrate 700 may be performed by any of the methods for forming the circuit pattern which are known in the circuit board field. According to the third exemplary embodiment of the present disclosure, the second circuit pattern 122 is made of the conductive material which is known in the circuit board field. For example, the second circuit pattern 122 may be made of copper.

Referring to FIG. 17, the second insulating layer 112 and the first circuit pattern 121 are formed.

According to the third exemplary embodiment of the present disclosure, the second insulating layer 112 is formed on the carrier substrate 700 and thus is formed to embed the second circuit pattern 122. According to the third exemplary embodiment of the present disclosure, the second insulating layer 112 is stacked on the carrier substrate 700 in the film type. Alternatively, the second insulating layer 112 is formed by being applied to the upper portion of the carrier substrate 700 in the liquid type.

According to the third exemplary embodiment of the present disclosure, the second insulating layer 112 is made of the composite polymer resin which is generally used as an interlayer insulating material. For example, the second insulating layer 112 may be made of the epoxy based resin, such as prepreg, ajinomoto build up film (ABF), FR-4, and bismaleimide triazine (BT).

According to the third exemplary embodiment of the present invention, the first circuit pattern 121 is formed on the upper surface of the second insulating layer 112 and is formed to protrude from the upper surface of the second insulating layer 112. Further, according to the third exemplary embodiment of the present invention, the via 123 is formed inside the second insulating layer 112 to electrically connect between the first circuit pattern 121 and the second circuit pattern 122. Here, the via 123 may be omitted according to the selection of those skilled in the art.

According to the third exemplary embodiment of the present invention, the first circuit pattern 121 and the via 123 may be formed by any of the methods for forming the circuit pattern and the via which are known in the circuit board field. Further, according to the third exemplary embodiment of the present disclosure, the first circuit pattern 121 and the via 123 are made of conductive materials which are generally used in the circuit board field. For example, the first circuit pattern 121 and the via 123 may be made of copper.

Referring to FIG. 18, the etching protective layer 130 is formed.

According to the third exemplary embodiment of the present disclosure, the etching protective layer 130 is formed to prevent the first circuit pattern 121 from being damaged at the time of forming the cavity (not illustrated) later. Therefore, the etching protective layer 130 is formed to enclose the first circuit pattern 121 which is positioned in a region in which the cavity (not illustrated) is formed. According to the third exemplary embodiment of the present disclosure, the etching protective layer 130 may be made of any material which may protect the first circuit pattern 121 from a cavity forming process. In this case, the etching protective layer 130 is made of a material different from that of the second insulating layer 112 and thus is made of a material which may be selectively stripped.

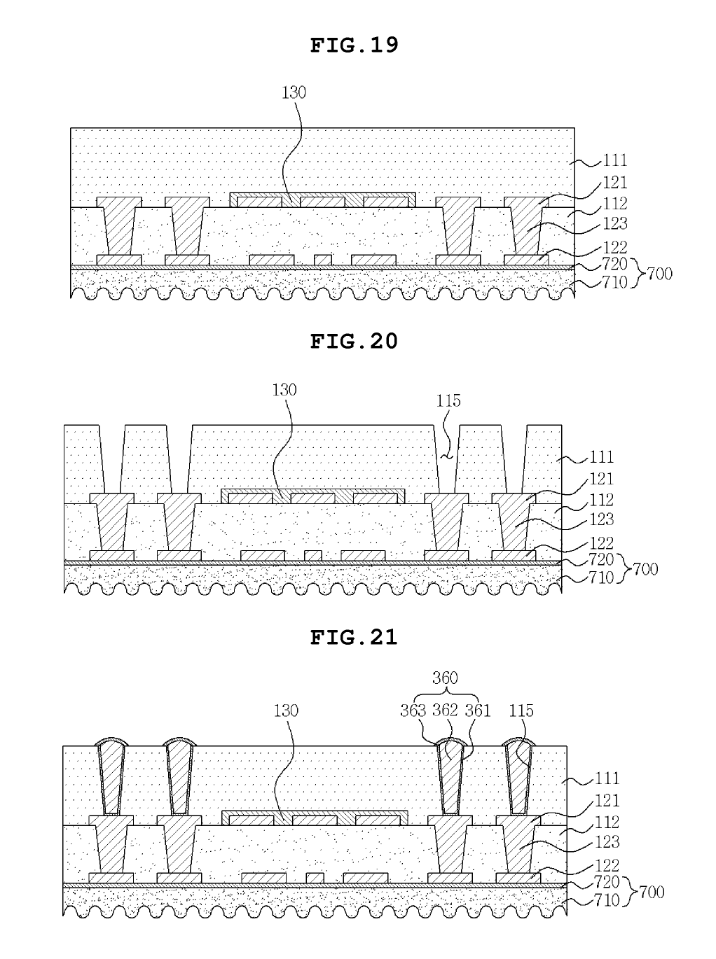

Referring to FIG. 19, the first insulating layer 111 is formed.

According to the third exemplary embodiment of the present disclosure, the first insulating layer 111 is formed on the second insulating layer 112 and thus is formed to embed the first circuit pattern 121 and the etching protective layer 130.

According to the third exemplary embodiment of the present disclosure, the first insulating layer 111 is stacked on the second insulating layer 112 in the film type or is formed by being applied in the liquid type.

Further, according to the third exemplary embodiment of the present disclosure, the first insulating layer 111 is made of the composite polymer resin which is generally used as the interlayer insulating material. For example, the first insulating layer 111 may be made of the epoxy based resin, such as prepreg, ajinomoto build up film (ABF), FR-4, and bismaleimide triazine (BT).

Referring to FIG. 20, the through hole 115 is formed.

According to the third exemplary embodiment of the present invention, the through hole 115 is formed to expose the first circuit pattern 121 by penetrating through the first insulating layer 111. The through hole 115 is formed in a region in which the external connection terminal (not illustrated) connected to the external components is formed. According to the third exemplary embodiment of the present disclosure, when the first insulating layer 111 is made of a photosensitive material, the through hole 115 may be formed by exposure and development processes. Alternatively, the though hole 115 may be formed by a laser drill. According to the third exemplary embodiment of the present disclosure, the method for forming a through hole 115 is not limited to the exposure and development processes and the laser drill. The through hole 115 may be formed by any of the methods for forming a hole in the circuit board field.

Referring to FIG. 21, the external connection terminal 360 is formed.

According to the third exemplary embodiment of the present invention, the external connection terminal 360 includes the seed layer 361, the first plating layer 362, and the second plating layer 363.

According to the third exemplary embodiment of the present disclosure, first, the seed layer 361 is formed on the inner wall of the through hole 115. According to the third exemplary embodiment of the present disclosure, the seed layer 361 is formed by the electroless plating method. For example, the seed layer 361 may be made of copper.

Next, the first plating layer 361 is formed in the through hole 115 formed with the seed layer 362 by the electroplating method. According to the third exemplary embodiment of the present disclosure, the first plating layer 362 is overplated on the through hole 115 and thus is formed to protrude from the upper surface of the first insulating layer 111. For example, the first plating layer 362 may be made of copper.

The seed layer 362 and the first plating layer 362 according to the third exemplary embodiment of the present invention are not necessarily made of only copper, but may be made of any of the conductive materials which are used for plating in the circuit board field.

According to the third exemplary embodiment of the present disclosure, the first plating layer 362 is formed and then the second plating layer 363 is formed. According to the third exemplary embodiment of the present disclosure, the second plating layer 363 is formed to enclose the first plating layer 362 which is exposed to the outside of the first insulating layer 111. The second plating layer 363 is formed by at least one of an electroless plating method and the electroplating method. Further, the second plating layer 363 may be made of a material different from that of the first plating layer 362 among the conductive materials which are used for plating in the circuit board field. For example, the second plating layer 363 may be made of tin (TiN).

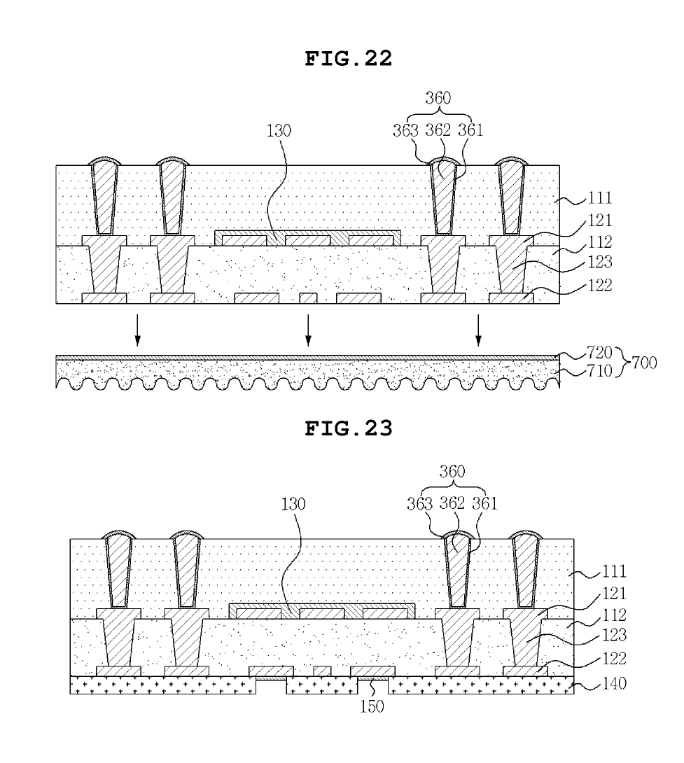

Referring to FIG. 22, the carrier substrate 700 is removed.

According to the third exemplary embodiment of the present disclosure, the carrier metal layer 720 is separated from the second insulating layer 112 and the second circuit pattern 122 to remove the carrier substrate 700. However, the method for removing a carrier substrate 700 is not limited thereto and therefore any of the methods for removing a carrier substrate 700 which is known in the circuit board field may be used.

Referring to FIG. 23, the solder resist layer 140 is formed.

According to the third exemplary embodiment of the present invention, the solder resist layer 140 is formed at the lower portion of the second insulating layer 112. Due to the removal of the carrier substrate 700, the second circuit pattern 122 is embedded in the second insulating layer 112 and the lower surface thereof is exposed to the outside. In this case, the solder resist layer 140 is formed to protect the lower surface of the second insulating layer 112, which is exposed to the outside, from the outside For example, the solder resist layer 140 protects the second insulating layer 112 from the soldering and oxidization phenomenon of the soldering process. According to the third exemplary embodiment of the present disclosure, the solder resist layer 140 is made of a heat resistant covering material.

Further, the solder resist layer 140 is formed to enclose the second insulating layer 112 to protect the second insulating layer 112 but a portion of the second insulating layer 112 is patterned to be exposed to the outside. In this case, the second insulating layer 112 which is exposed by the solder resist layer 140 is a portion which is connected to the external components. According to the third exemplary embodiment of the present disclosure, the solder resist layer 140 is patterned by exposure and development processes.

Further, although not illustrated in FIG. 23, the solder resist layer 140 is patterned and then the surface treatment layer (not illustrated) is formed on the second circuit pattern 122 which is exposed to the outside. The surface treatment layer (not illustrated) is formed to prevent the second circuit pattern 122 which is exposed to the outside from corroding and being oxidized due to the outside environment.

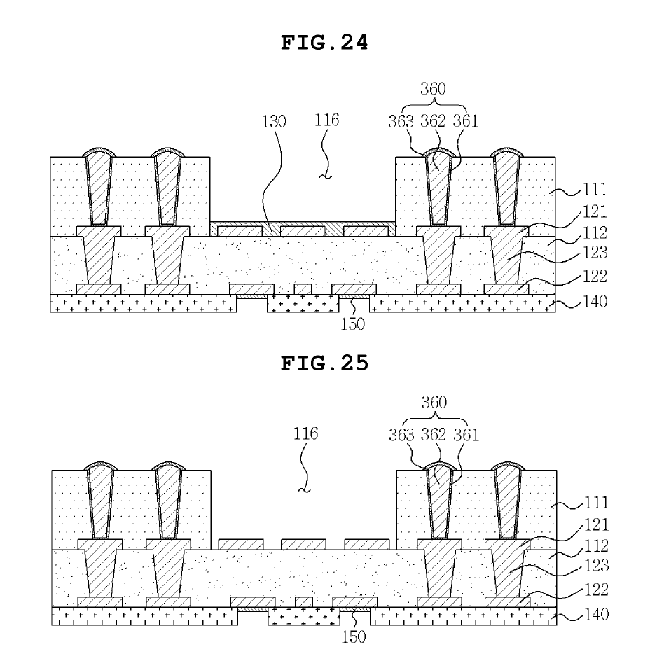

Referring to FIG. 24, the cavity 116 is formed.

According to the third exemplary embodiment of the present disclosure, the cavity 116 is formed in the first insulating layer 111. The cavity 116 is formed to expose the etching protective layer 130. According to the third exemplary embodiment of the present disclosure, the cavity 116 is formed by the exposure and development processes. However, the method for forming a cavity 116 is not limited thereto. For example, the cavity 116 may also be formed by the laser drill.

Referring to FIG. 25, the etching protective layer (FIG. 24) is removed.

According to the third exemplary embodiment of the present disclosure, the etching protective layer (FIG. 24) is removed and thus the first circuit pattern 122 which is formed at the lower portion of the cavity 116 is exposed to the outside.

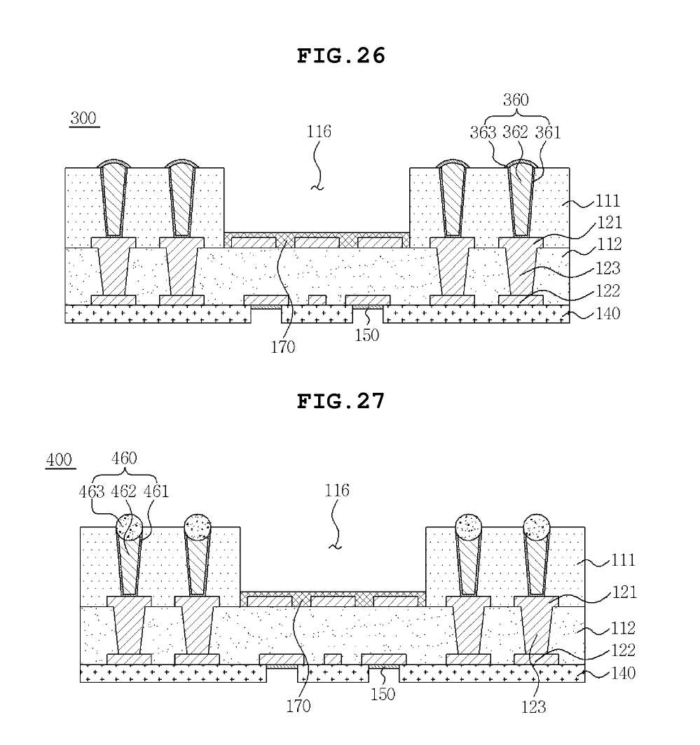

Referring to FIG. 26, the external protective layer 170 is formed.

According to the third exemplary embodiment of the present disclosure, the external protective layer 170 is formed to protect the first circuit pattern 121 which is exposed to the outside from the outside environment by the cavity 116. Therefore, the external protective layer 170 is formed to enclose the first circuit pattern 121 within the cavity 116. The external protective layer 170 may be made of any material which may protect the first circuit pattern 121 from the outside. For example, the external protective layer 170 is made of the same material as the solder resist layer 140.

As such, the package board 300 according to the third exemplary embodiment of the present invention is formed by the processes illustrated in FIGS. 16 through 26.

### Fourth Exemplary Embodiment

FIG. 27 is an exemplified diagram illustrating a package board according to a fourth exemplary embodiment of the present disclosure.

The first insulating layer 111, the second insulating layer 112, the first circuit pattern 121, the second circuit pattern 122, the via 123, the solder resist layer 140, the surface treatment layer 150, and the external protective layer 170 of the package board 400 according to the fourth exemplary embodiment of the present invention are the same as the package board 300 according to the third exemplary embodiment of the present invention of FIG. 15. Further, an external connection terminal 460 of the package board 400 according to the fourth exemplary embodiment of the present invention is the same as the external connection terminal 260 according to the second exemplary embodiment of the exemplary embodiment of FIG. 11.

That is, the package board 400 according to the exemplary embodiment of the present invention has a structure in which the second circuit pattern 122 is embedded in the inside of the first insulating layer 11. Further, the external connection terminal 460 of the package board 400 has a structure in which a first plating layer 462 collapses from the upper surface of the first insulating layer 111 and a conductive ball 463 is formed on the first plating layer 462.

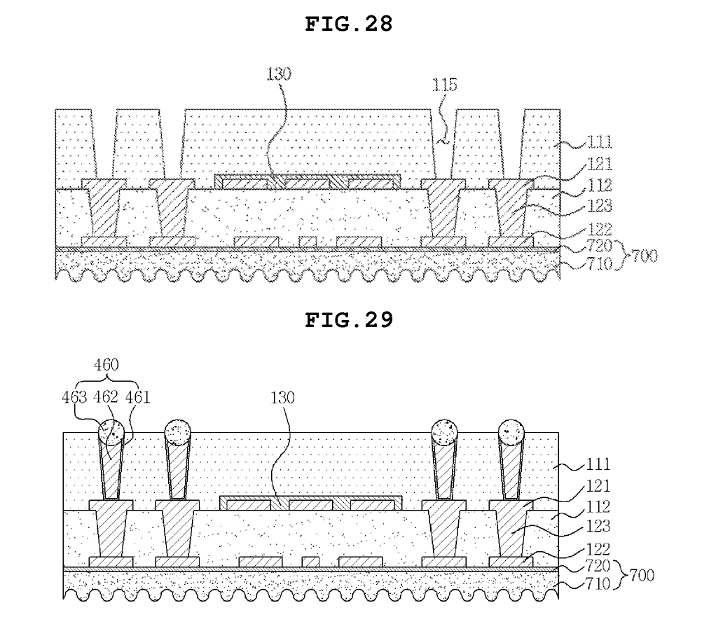

FIGS. 28 through 30 are exemplified diagrams illustrating a method of manufacturing the package board according to the fourth exemplary embodiment of the present invention.

Referring to FIG. 28, the second circuit pattern 122, the second insulating layer 112, the first circuit pattern 121, the etching protective layer 130, and the first insulating layer 111 formed with the through hole 115 are formed on the carrier substrate 700.

The processes from forming the second circuit pattern 122 to forming the through hole 115 on the carrier substrate 700 according to the exemplary embodiment of the present invention will refer to FIGS. 16 through 20.

Referring to FIG. 29, the external connection terminal 460 is formed.

According to a fourth exemplary embodiment of the present disclosure, the process of forming an external connection terminal 460 will refer to FIG. 13.

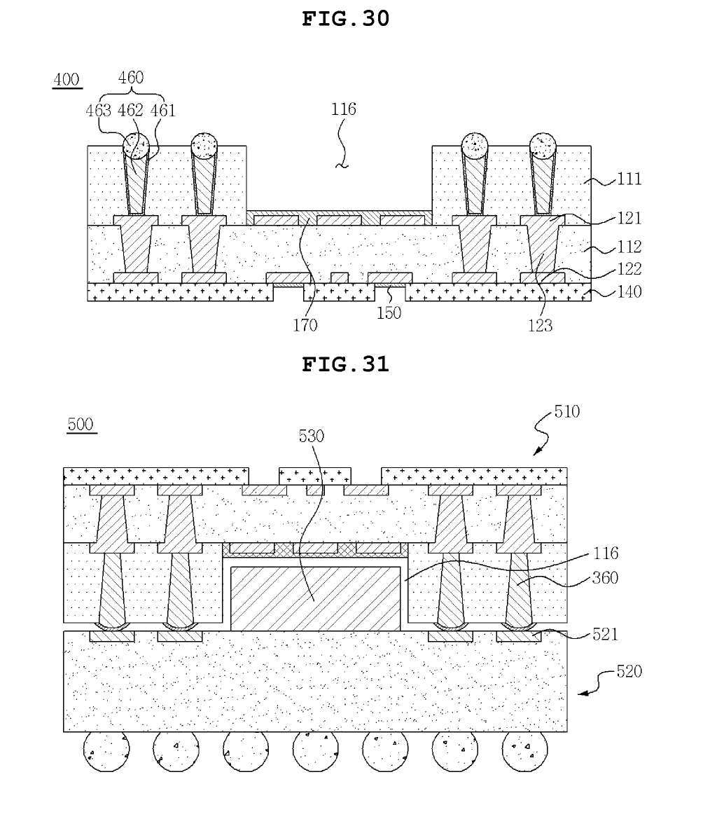

Referring to FIG. 30, the carrier substrate 700 is removed and the solder resist layer 140, the cavity 116, and the external protective layer 170 are formed.

According to the fourth exemplary embodiment of the present invention, the processes from removing the carrier substrate 700 to forming the external protective layer 170 will refer to FIGS. 22 through 26.

As such, the package board 400 according to the fourth exemplary embodiment of the present invention is formed by the processes illustrated in FIGS. 28 through 30.

Stack Type Package

FIG. 31 is an exemplified diagram illustrating the package board according to the exemplary embodiment of the present disclosure.

Referring to FIG. 31, a stack type package 500 according to the exemplary embodiment of the present invention includes a first package board 510, a second package board 520, and electronic devices 530.

Although not illustrated in the drawings, the second package board 520 according to the exemplary embodiment of the present invention is formed as the insulating layer and a circuit layer of at least one layer. As the second package board 520 according to the exemplary embodiment of the present invention, any known board on which the electronic devices 530 may be mounted may be used. The second package board 520 according to the exemplary embodiment of the present invention has an external connection pad 521 formed on the upper surface thereof. Here, the external connection pad 521 contacts the external connection terminal 360 of the first package board 510.

The electronic devices 530 according to the exemplary embodiment of the present invention are mounted on the second package board 520.

The first package board 510 according to the exemplary embodiment of the present invention is positioned on the second package board 520 and the electronic devices 530. The first package board 510 according to the exemplary embodiment of the present invention includes the cavity 116 into which at least some of the electronic devices 530 are inserted. Further, the first package board 510 includes the external connection terminals 360 formed at both sides of the cavity 116 or therearound by the plating method. According to the exemplary embodiment of the present invention, the first package board 510 is the package board 300 according to the third exemplary embodiment of the present invention. However, the first package board 510 is not limited to the package board 300 according to the exemplary embodiment of the present invention. For example, as the first package board 510, any of the package boards according to the first to fourth exemplary embodiments of the present invention may be used.

According to the exemplary embodiment of the present invention, even though the electronic device 530 is disposed on the second package board 520 by the first package board 510 including the cavity 116 and the external connection terminal 360, the spaced distance between the first package board 510 and the second package board 520 is short. Further, the stack type package board 500 according to the exemplary embodiment of the present invention may directly contact the external connection terminal 160 and the second package board 520 by the foregoing short spaced distance. Therefore, the existing large solder ball may be omitted. Further, according to the exemplary embodiment of the present invention, the portion protruding from the first package board 510 may be reduced at the external connection terminal 160 due to the short spaced distance and thus the fine pitch may be implemented. Further, the overall thickness of the stack type package 500 according to the exemplary embodiment of the present invention may be reduced since the electronic device 530 is inserted into the cavity 116 of the first package board 510.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A package board, comprising:
a first insulating layer formed with a cavity; and
an external connection terminal formed to penetrate through the first insulating layer and have one end protruding to an outside of one surface of the first insulating layer.

2. The package board of claim 1, wherein the external connection terminal includes:
a first plating layer formed to penetrate through the first insulating layer and formed to protrude to the outside of the one surface of the first insulating layer; and
a second plating layer formed on the first plating layer protruding to the outside.

3. The package board of claim 2, wherein the first plating layer and the second plating layer are made of different materials.

4. The package board of claim 1, wherein the external connection terminal includes:
a first plating layer formed inside the first insulating layer and formed in a form collapsing from the one surface of the first insulating layer; and
conductive balls formed on the first plating layer, some of the conductive balls being formed to be positioned inside the first insulating layer and others being formed to be positioned outside the first insulating layer.

5. The package board of claim 1, further comprising:
a first circuit pattern formed on the other surface of the first insulating layer and bonded to the other end of the external connection terminal.

6. The package board of claim 5, wherein the first circuit pattern is formed to be embedded in the first insulating layer.

7. The package board of claim 5, wherein a portion of the first circuit pattern is positioned in the cavity.

8. The package board of claim 7, further comprising:
an external protective layer formed to enclose a first circuit pattern which is positioned in the cavity.

9. The package board of claim 5, further comprising;
a second insulating layer formed on the other surface of the first insulating layer; and
a second circuit pattern formed on the other surface of the second insulating layer.

10. A stack type package, comprising:
a first package board including a first insulating layer formed with a cavity; and
an external connection terminal formed to penetrate through the first insulating layer and having one end protruding to an outside of one surface of the first insulating layer; a second package board positioned under the first package board and having an external connection pad formed on an upper surface thereof; and
an electronic device disposed at an upper portion of the second package board and disposed in a cavity of the first package board,
wherein the external connection terminal contacts the external connection pad.

11. The stack type package of claim 10, wherein the external connection terminal further includes:
a first plating layer formed to penetrate through the first insulating layer and formed to protrude to the outside of the one surface of the first insulating layer; and
a second plating layer formed on the first plating layer protruding to the outside.

12. The stack type package of claim 11, wherein the first plating layer and the second plating layer are made of different materials.

13. The stack type package of claim 10, wherein the external connection terminal includes:
a first plating layer formed inside the first insulating layer and formed in a form collapsing from the one surface of the first insulating layer; and
conductive balls formed on the first plating layer, some of the conductive balls being formed to be positioned inside the first insulating layer and others being formed to be positioned outside the first insulating layer.

14. The stack type package of claim 10, further comprising:
a first circuit pattern formed on the other surface of the first insulating layer and bonded to the other end of the external connection terminal.

15. A method for manufacturing a package board, comprising:
forming a first insulating layer;
forming an external connection terminal formed to penetrate through the first insulating layer and have one end protruding to an outside of one surface of the first insulating layer; and
forming a cavity on one surface of the first insulating layer.

16. The method of claim 15, wherein the forming of the external connection terminal includes:
forming a through hole penetrating through the first insulating layer;
forming a seed layer on an inner wall of the through hole by an electroless plating method; and
forming a first plating layer in a through hole formed with the seed layer by an electroplating method, and
the first plating layer is formed to protrude to an outside of one surface of the first insulating layer.

17. The method of claim 16, further comprising:
after the forming of the first plating layer, forming a second plating layer at a portion protruding to the outside of the first insulating layer in the first plating layer.

18. The method of claim 15, wherein the forming of the external connection terminal includes:
forming a through hole penetrating through the first insulating layer;
forming a seed layer on an inner wall of the through hole by an electroless plating method;
forming a first plating layer in a through hole formed with the seed layer by an electroplating method, and
forming conductive balls on the first plating layer, and
the first plating layer is formed to collapse from the one surface of the first insulating layer and some of the conductive balls are positioned inside the first insulating layer and others are formed to protrude to the outside of the first insulating layer.

19. The method of claim 15, further comprising:
prior to the forming of the first insulating layer, forming a second insulating layer, a first circuit pattern formed on one surface of the second insulating layer, and a second circuit pattern formed on the other surface thereof,
wherein the first insulating layer is formed on one surface of the second insulating layer to embed the first circuit pattern.

20. The method of claim 19, wherein the first circuit pattern is formed to protrude from the second insulating layer.

21. The method of claim 19, further comprising:
prior to the forming of the first insulating layer, forming an etching protective layer enclosing a first circuit pattern positioned in a region in which the cavity is formed among the first circuit patterns.

22. The method of claim 21, wherein in the forming of the cavity, the cavity is formed to expose the etching protective layer.

23. The method of claim 22, further comprising:
after the forming of the cavity, removing the etching protective layer.

24. The method of claim 19, wherein in the forming of the second insulating layer, the first circuit pattern, and the second circuit pattern, a core substrate including the second insulating layer, the first circuit pattern, and the second circuit pattern is provided.

25. The method of claim 19, wherein the forming of the second insulating layer, the first circuit pattern, and the second circuit pattern includes:
preparing a carrier substrate;
forming a second circuit pattern on one surface of the carrier substrate;
forming a second insulating layer formed on one surface of the carrier substrate to embed the second circuit pattern; and
forming the first circuit pattern on one surface of the second insulating layer.
